(19) United States
(12) Patent Application Publication
(10) Pub. No.: US 2012/0227996 A1
(43) Pub. Date: Sep. 13, 2012

(54) CABLE STRUCTURE WITH METAL DOPED FIBERS AND METHODS FOR MAKING THE SAME

(75) Inventors: John B. Ardisana, II, San Francisco, CA (US); Edward Siahaan, San Francisco, CA (US); Eric Jol, San Jose, CA (US)

(73) Assignee: APPLE INC., Cupertino, CA (US)

(21) Appl. No.: 13/250,987

(22) Filed: Sep. 30, 2011

Related U.S. Application Data
(60) Provisional application No. 61/450,351, filed on Mar. 8, 2011.

(51) Int. Cl. H05K 9/00; D04C 1/06; D04C 1/02

(52) U.S. Cl. 174/34; 87/6; 87/9

(57) ABSTRACT

Cables with braided shields constructed from metal-doped fibers and methods for making the same are disclosed. This braided shield maintains the electrical conductivity of a conventional all-metal braided shield, but is less stiff. This allows for a much more flexible cable and increased cable flex life because the metal-doped fibers are not as sensitive to bending fatigue as their all metal counterparts.

This application claims the benefit of U.S. Provisional Patent Application No. 61/450,351, filed Mar. 8, 2011, the disclosure of which is incorporated by reference herein in its entirety.

### BACKGROUND

Cables are commonly used with electronic devices such as computers, cellphones, and portable media devices. When cables are subject to repeated physical manipulations that exert bend and strain forces on the cable, the cable can eventually break or tear. Smaller diameter cables and cables used in connection with portable electronic devices are generally more susceptible to breakage because they are more frequently handled by being bent, pulled, tangled, or wrapped. What is needed are cables that are better able to withstand use stresses so that the life expectancy of such cables is increased.

### SUMMARY

Cables with braided shields constructed from metal-doped fibers and methods for making the same are disclosed. These braided shields maintain the electrical conductivity of a conventional all-metal braided shield, but are less stiff. This allows for a much more flexible cable and increased cable flex life because the metal-doped fibers are not as sensitive to bending fatigue as their all metal counterparts.

### BRIEF DESCRIPTION OF THE DRAWINGS

The above and other aspects and advantages of the invention will become more apparent upon consideration of the following detailed description, taken in conjunction with accompanying drawings, in which like reference characters refer to like parts throughout, and in which:

FIG. 1 shows an illustrative view of a cable in accordance with an embodiment of the invention; and

FIG. 2 shows an illustrative process for manufacturing a cable according to an embodiment of the invention.

### DETAILED DESCRIPTION OF THE DISCLOSURE

Cables constructed according to embodiments of this invention incorporate a high strength, low fatigue braided shield constructed from metal-doped fibers. This braided shield maintains the electrical conductivity of a conventional all-metal braided shield, but is less stiff. This allows for a much more flexible cable and increased cable flex life because the metal-doped fibers are not as sensitive to bending fatigue as their all metal counterparts.

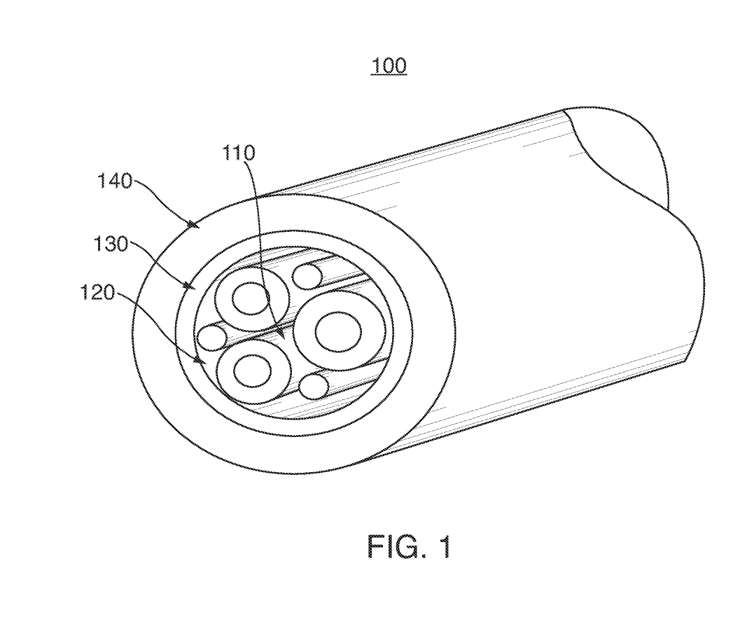

FIG. 1 shows an illustrative cross-sectional view of cable 100 in accordance with an embodiment of the invention. Cable 100 may have any suitable size and shape and may be used for any number of suitable purposes. For example, cable 100 can be used as a headset cable, a USB cable, a video cable such as an HDMI cable or display port cable, or a power cable. In some embodiments, cable 100 can have a diameter ranging between 1/16^{th} of an inch to ¼^{th} of an inch, though it is understood that cable 100 can have any suitable diameter.

Cable 100 can include conductor bundle 110, electromagnetic interference (“EMI”) shield 120, braided shield 130, and jacket 140. Conductor bundle 110 can form the core of cable 100 and includes one or more conductors for conveying signals and/or power. The number of conductors included in conductor bundle 110 depends on the desired function of cable 100.

EMI shield 120 surrounds conductor bundle 110 to provide electromagnetic shielding. EMI shield 120 can be constructed from aluminum, mylar, aluminized mylar, or other suitable material. EMI shielding 120 can be bound to conductor bundle 110 with a binding agent (not shown).

Braided shield 120 surrounds EMI shield 120 and conductor bundle 110. Braided shield 120 can provide grounding for cable 110 and/or additional electromagnetic shielding. Braided shield 120 can be constructed from fibers that are coated with a conductive metal. The fibers can be synthetic or natural fibers. Synthetic fibers can include, for example, polymer fibers such as polyester, vinyl ester, nylon, Kevlar, or fiberglass. Another example of a synthetic fiber is carbon fiber, which can be reinforced with a polymer. Examples of natural fibers can include cotton or hemp.

The fibers can be coated with any suitable conductive metal such as silver, gold, nickel, aluminum, zinc, brass, bronze, iron, steel, platinum, any combination thereof or alloys thereof. The fibers may be dip or spray coated with metal. A specific example of a metal-doped fiber is a silver coated Kevlar fiber. Another specific example is a nickel coated carbon fiber.

Braided shield 130 can be braided directly onto EMI shield 130 according to any suitable braided pattern. The metal-doped fibers can be woven together around EMI shield 130 to form a weave of such fibers. The weave may comprise the same metal-doped fiber or a combination of different metal-doped fibers. The density of the weave may vary; however, it may be desirable to minimize interstitial spacing. In some embodiments, braided shield 130 can be weaved with a density sufficient to perform the same electromagnetic shielding function of EMI shield 120. In such an embodiment, EMI shield 120 can be eliminated.

In another embodiment, braided shield 130 can be woven as a separate component that is slid over conductor bundle 110 and EMI shield 120.

Some fibers have a tensile strength that is higher than a metal counterpart (e.g., copper). In other words, such fibers have a greater modulus of elasticity or greater capacity for plastic deformation than certain metal counterparts. Such fibers can also have a smaller cross-section than the metal counterpart, thereby resulting in a smaller braided shield cross-section. This in turn enables cable 100 to have a smaller cross-section.

Jacket 140 encapsulates braided shield 130, EMI shield 120, and conductor bundle 110 to form the outermost layer of cable 100. Jacket 140 can be any suitable material such as, for example, a thermoplastic, silicon, or urethane. Jacket 140 can bond braided shield 130 to EMI shield 120 so that it becomes permanently integrated into cable 100.

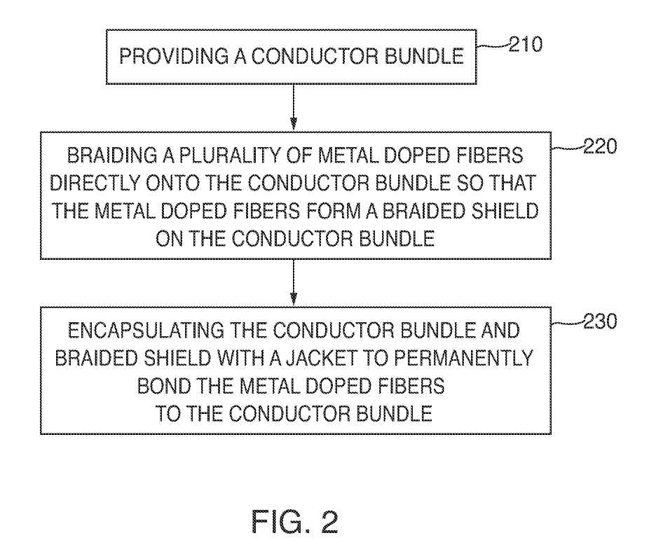

FIG. 2 shows an illustrative process for manufacturing a cable having a braided shield constructed from metal-doped fibers according to an embodiment of the invention. Beginning at step 210, a conductor bundle is provided. The conductor bundle can be any suitable combination of conductors. The conductor bundle can be sourced from a spool or a combination of spools and fed to a braiding apparatus.

At step 220, a plurality of metal-doped fibers are braided directly onto the conductor bundle so that the metal doped fibers form a braided shield. The braided shield can have any suitable pattern and can include fibers of the same type or multiple different types. The density of the pattern can depend on several factors, including the speed at which the conductor bundle is fed through the braiding the machine, the number of fibers being braided onto the bundle, and the weave pattern.

At step 230, the conductor bundle and braided shield are encapsulated with a jacket to permanently bond the metal doped fibers to the conductor. It is understood that additional steps may be added without departing from the spirit of the invention. For example, a step may be inserted in between steps 210 and 220 to encapsulate the conductor bundle with an electromagnetic interference shield.

The described embodiments of the invention are presented for the purpose of illustration and not of limitation.

What is claimed is:

1. A cable comprising:
a conductor bundle;
an electromagnetic interference (EMI) shield that encapsulates the conductor bundle;
a braided shield comprising a plurality of metal doped fibers that are braided around the EMI shield; and
a jacket that encapsulates the braided shield, EMI shield, and conductor bundle.

2. The cable of claim 1, wherein the metal doped fibers comprise a polymer fiber and a conductive metal.

3. The cable of claim 1, wherein the metal doped fibers comprise Kevlar fibers coated with a conductive metal.

4. The cable of claim 3, wherein the conductive metal is gold, silver, nickel, or a combination thereof.

5. The cable of claim 1, wherein the metal doped fibers comprise carbon fiber and a conductive metal.

6. The cable of claim 5, wherein the conductive metal is gold, silver, nickel, or a combination thereof.

7. The cable of claim 1, wherein the metal doped fibers comprise a natural fiber and a conductive metal.

8. The cable of claim 1, wherein the EMI shield is constructed from aluminum, mylar, or a combination thereof.

9. The cable of claim 1, wherein the jacket bonds the braided shield to the EMI shield.

10. The cable of claim 1, wherein the doped metal fibers are braided according to a predetermined weave pattern.

11. The cable of claim 1, wherein the conductor bundle comprises at least one conductor.

12. A method for making a cable, the method comprising:
providing a conductor bundle;
braiding a plurality of metal doped fibers directly onto the conductor bundle so that the metal doped fibers form a braided shield on the conductor bundle; and
encapsulating the conductor bundle and braided shield with a jacket to permanently bond the metal doped fibers to the conductor bundle.

13. The method of claim 12, further comprising encapsulating the conductor bundle with an electromagnetic shield, wherein the braided shield is braided directly onto the electromagnetic shield.

14. The method of claim 12, wherein the plurality of metal-doped fibers are the same metal-doped fiber.

15. The method of claim 12, wherein the plurality of metal-doped fibers comprise at least two different metal-doped fibers.

16. A cable comprising:
a conductor bundle;
a braided shield comprising a plurality of metal doped fibers that are braided around the conductor bundle; and
a jacket that encapsulates the braided shield and conductor bundle.

17. The cable of claim 16, wherein the cable has a diameter ranging between 1/16^{th} of an inch and ¼^{th} of an inch.

18. The cable of claim 16, wherein the metal doped fibers comprise a polymer fiber and a conductive metal.

19. The cable of claim 16, wherein the metal doped fibers comprise a carbon fiber and a conductive metal.

20. The cable of claim 16, wherein the braided cable provides grounding and electromagnetic interference shielding.

21. The cable of claim 16, wherein the jacket comprises a thermoplastic.
